(19) United States
(12) Patent Application Publication
(10) Pub. No.: US 2014/0295579 A1
(43) Pub. Date: Oct. 2, 2014

(54) METHOD OF PATTERNING MTJ STACK

(71) Applicant: Yimin Guo, San Jose, CA (US)

(72) Inventor: Yimin Guo, San Jose, CA (US)

(73) Assignee: T3MEMORY, INC., Saratoga, CA (US)

(21) Appl. No.: 14/225,419

(22) Filed: Mar. 25, 2014

Related U.S. Application Data
(60) Provisional application No. 61/806,742, filed on Mar. 29, 2013.

(51) Int. Cl. H01L 43/12

(52) U.S. Cl. CPC H01L 43/12
USPC 438/3

(57) ABSTRACT

This invention comprises methods to form isolated magnetic tunneling junction (MTJ) memory element with small footprint using oxygen-ion implantation. After patterned resist is form on an MTJ film, the substrate is subject to a series of ion implantations outside the mask areas to subsequently implant Mg and oxygen ions into the exposed MTJ junction region, followed by high temperature rapid thermal annealing. Using such a process, implanted oxygen ions, Mg ions and non-oxidized Mg atoms in MTJ stack form highly resistive MgO crystalline and the ion implanted area is converted into electrically insulated metal oxide, creating a shape well-defined MTJ memory element with ultra-small dimensions and vertical edges.

### RELATED APPLICATIONS

This application claims the priority benefit of U.S. Provisional Application No. 61/806,742 filed on Mar. 29, 2013, which is incorporated herein by reference.

### BACKGROUND OF THE INVENTION

1. Field of the Invention

This invention relates generally to spin-electronic devices, more particularly to a magnetic tunnel junction and methods for patterning the same.

2. Description of the Related Art

Magnetoresistive elements having magnetic tunnel junctions (also called MTJs) have been used as magnetic sensing elements for years. In recent years, magnetic random access memories (hereinafter referred to as MRAMs) using the magnetoresistive effect of MTJ have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed layer that is located on the opposite side from the recording layer and maintains a predetermined magnetization direction.

As a write method to be used in such magnetoresistive elements, there has been suggested a write method (spin torque transfer switching technique) using spin momentum transfers. According to this method, the magnetization direction of a recording layer is reversed by applying a spin-polarized current to the magnetoresistive element. Furthermore, as the volume of the magnetic layer forming the recording layer is smaller, the injected spin-polarized current to write or switch can be also smaller. Accordingly, this method is expected to be a write method that can achieve both device miniaturization and lower currents.

Further, as in a so-called perpendicular MTJ element, both two magnetization films have easy axis of magnetization in a direction perpendicular to the film plane due to their strong magnetic crystalline anisotropy, shape anisotropies are not used, and accordingly, the device shape can be made smaller than that of an in-plane magnetization type. Also, variance in the easy axis of magnetization can be made smaller. Accordingly, by using a material having a large magnetic crystalline anisotropy, both miniaturization and lower currents can be expected to be achieved while a thermal disturbance resistance is maintained.

There has been a known technique for achieving a high MR ratio in a perpendicular magnetoresistive element by forming a crystallization acceleration film that accelerates crystallization and is in contact with an interfacial magnetic film having an amorphous structure. As the crystallization acceleration film is formed, crystallization is accelerated from the tunnel barrier layer side, and the interfaces with the tunnel barrier layer and the interfacial magnetic film are matched to each other. By using this technique, a high MR ratio can be achieved. However, where a MTJ is formed as a device of a perpendicular magnetization type, the materials of the recording layer typically used in an in-plane MTJ for both high MR and low damping constant as required by low write current application normally don't have enough magnetic crystalline anisotropy to achieve thermally stable perpendicular magnetization against its demagnetization field. In order to obtain perpendicular magnetization with enough thermal stability, the recording layer has to be ferromagnetic coupled to additional perpendicular magnetization layer, such as TbCoFe, or CoPt, or multilayer such as (Co/Pt)n, to obtain enough perpendicular anisotropy. Doing so, reduction in write current becomes difficult due to the fact that damping constant increases from the additional perpendicular magnetization layer and its associated seed layer for crystal matching and material diffusion during the heat treatment in the device manufacturing process.

In a spin-injection MRAM using a perpendicular magnetization film, a write current is proportional to the perpendicular anisotropy, the damping constant and inversely proportional to a spin polarization, and increases in proportional to a square of an area size. Therefore, reduction of the damping constant, increase of the spin polarization and reduction of an area size are mandatory technologies to reduce the write current.

Besides a write current, the stability of the magnetic orientation in a MRAM cell as another critical parameter has to be kept high enough for a good data retention, and is typically characterized by the so-called thermal factor which is proportional to the perpendicular anisotropy as well as the volume of the recording layer cell size. Although a high perpendicular anisotropy is preferred in term of a high thermal disturbance resistance, an increased write current is expected as a cost.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus reversing the direction of magnetization of the recording layer in MTJ. Majorities of cell-to-cell variations come from the MTJ cell patterning process.

The MTJ patterning process becomes one of the most challenging aspects of manufacturing. Conventional techniques utilized to pattern small dimensions in a chip, such as ion milling etching (IBE) or reactive ion etching (RIE), having been less than satisfactory when applied to magnetic tunnel junction stacks used for MRAM. In most cases when these techniques are used, it is very difficult or almost impossible to cleanly remove etched materials without partial damages to magnetic tunnel junction properties and electric current shunting. In a RIE etching of magnetic material, physical sputtering is still the major component which unavoidable results in the formation of re-deposited residues that can short circuit the junctions of the MTJ or create shunting channel of the MTJ, yielding high resistance variations and serious reliability issues.

Another problem of conventional patterning techniques is the degradation of the recording layer and reference layer in the MTJ, due to corrosion caused by chemical residue remaining after etching. Exposure to reactive gases during refilling deposition of dielectrics such as silicon dioxide or silicon nitride after the MTJ etching can also cause corrosion. After refilling of dielectric material, a chemical mechanic polishing process is required to smooth out the top surface for bit line fabrication, which introduces a big manufacturing challenging as well as high cost and further corrosion.

Thus, it is desirable to provide a greatly improved method or innovative method that enables well-controllable and low cost fabrication in MTJ patterning while eliminating damage, degradation and corrosion.

### BRIEF SUMMARY OF THE PRESENT INVENTION

The present invention comprises a method of patterning a magnetic tunnel junction of a magnetoresistive element for spin-electronic devices, such as MRAM, magnetic sensor and magnetic recording head. The magnetoresistive element in an MRAM is sandwiched between an upper electrode and a lower electrode, and a spin polarized current is bi-directionally supplied to the magnetoresistive element for data recording, and a select transistor is electrically connected between the magnetoresistive element and the write circuit.

According to methods to be described hereinafter, an MTJ stack is first formed on a substrate followed by a deposition of a hard mask. A first area of the MTJ stack is masked while a second area of the MTJ is exposed to a series of ion implantations. The exposed area, including the recording layer, is then converted to a highly resistive non-magnetic compound by forming of MgO crystalline structure. As an option, a conventional photo-lithographic patterning process is utilized to make a larger footprint mask overlaid on the first area and further etch away the exposed area.

According to a first aspect of the invention, an MTJ stack is formed on a substrate, the MTJ consists of a recording layer, a reference layer and a MgO tunnel barrier layer disposed between the recording layer and the reference layer, a protective cap layer and an optional MgO intermediate layer provided on a surface of the recording layer, which is opposite to a surface of the recording layer where the tunnel barrier layer is provided, and there is provided a method of patterning a magnetic tunnel junction which comprises:
forming a hard mask having an opening on the cap layer;
ion-implanting oxygen atoms to the depth position to the MgO tunnel barrier layer from a surface of the cap layer exposed in the opening of the mask;
carrying out a thermal annealing with respect to the substrate to oxidize an ion implantation region and re-crystallized MgO layer so that a highly oxidized MgO layer having a greatly increased resistance is formed and an oxidized recording layer having a highly increased resistance and zero or near zero magnetization moment is formed in the opening of the mask; and forming a dielectric region outside of the photo-mask on the substrate and a functional magnetoresistive element underneath the photo-mask on the substrate;
removing the photo-mask.

According to a second aspect of the invention, an MTJ stack is formed on a substrate, the MTJ consists of a recording layer, a reference layer and a MgO tunnel barrier layer disposed between the recording layer and the reference layer, a protective cap layer and an optional MgO intermediate layer provided on a surface of the recording layer, which is opposite to a surface of the recording layer where the tunnel barrier layer is provided, and there is provided a method of patterning a magnetic tunnel junction which comprises:
forming a hard mask having an opening on the cap layer;
ion-implanting Mg atoms to the depth position of the MgO tunnel barrier layer from a surface of the cap layer exposed in the opening of the mask;
ion-implanting oxygen atoms to the depth position to the MgO tunnel barrier layer from a surface of the cap layer exposed in the opening of the mask;
carrying out a thermal annealing with respect to the substrate to oxidize an ion implantation region and re-crystallized MgO layer so that a highly oxidized MgO layer having a greatly increased resistance is formed and an oxidized recording layer having a highly increased resistance and zero or near zero magnetization moment is formed in the opening of the mask; and forming a dielectric region outside of the photo-mask on the substrate and a functional magnetoresistive element underneath the photo-mask on the substrate;
removing the photo-mask.

According to a third aspect of the invention, an MTJ stack is formed on a substrate, the MTJ consists of a recording layer, a reference layer and a MgO tunnel barrier layer disposed between the recording layer and the reference layer, a protective cap layer and an optional MgO intermediate layer provided on a surface of the recording layer, which is opposite to a surface of the recording layer where the tunnel barrier layer is provided, and there is provided a method of patterning a magnetic tunnel junction which comprises:
forming a hard mask having an opening on the cap layer;
etching or milling a top portion of the MTJ stack;
ion-implanting Mg atoms to the depth position of the MgO tunnel barrier layer from a surface of the cap layer exposed in the opening of the mask;
ion-implanting oxygen atoms to the depth position to the MgO tunnel barrier layer from a surface of the cap layer exposed in the opening of the mask;
carrying out a thermal annealing with respect to the substrate to oxidize an ion implantation region and re-crystallized MgO layer so that a highly oxidized MgO layer having a greatly increased resistance is formed and an oxidized recording layer having a highly increased resistance and zero or near zero magnetization moment is formed in the opening of the mask; and forming a dielectric region outside of the photo-mask on the substrate and a functional magnetoresistive element underneath the photo-mask on the substrate;
refilling a dielectric layer;
removing the photo-mask;
flattening the top surface by a CMP process.

Various embodiments will be described hereinafter with reference to the companying drawings. The drawings are schematic or conceptual, and the relationships between the thickness and width of portions, the proportional coefficients of sizes among portions, etc., are not necessarily the same as the actual values thereof.

### BRIEF DESCRIPTION OF THE DRAWINGS

FIG. 1(A) is a first exemplary cross-section of an MTJ film deposited on a substrate;

FIG. 1(B) is a second exemplary cross-section of an MTJ film deposited on a substrate;

FIG. 1(C) is a third exemplary cross-section of an MTJ film deposited on a substrate;

FIG. 2 Oxygen ions are implanted into the buried MTJ multi-layers between top capping layer and bottom seed, (A) cross section view, (B) top view ;

FIG. 3 (A) Some oxygen getter material is implanted into the MTJ region, (B) followed by oxygen ion implantation.

### DETAILED DESCRIPTION OF THE INVENTION

In general, according to each embodiment, there is provided a magnetoresistive element, formed on a substrate, comprising:
a recording layer having magnetic anisotropy in a film surface and having a variable magnetization direction;
a reference layer having magnetic anisotropy in a film surface and having an invariable magnetization direction;
a tunnel barrier layer provided between the recording layer and the reference layer;
an intermediate barrier layer provided on a surface of the recording layer, which is opposite to a surface of the recording layer where the tunnel barrier layer is provided;
a protective cap layer provided on top surface of above stack.

The following detailed descriptions are merely illustrative in nature and are not intended to limit the embodiments of the subject matter or the application and uses of such embodiments. Any implementation described herein as exemplary is not necessarily to be construed as preferred or advantageous over other implementations. Furthermore, there is no intention to be bound by any expressed or implied theory presented in the preceding technical field, background, brief summary, or the following detailed description.

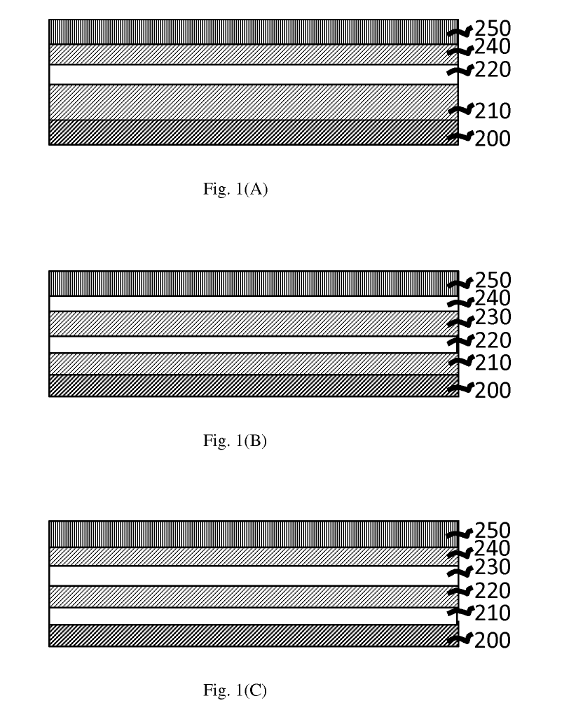

In this invention disclosure, we describe a method to form an isolated MTJ sensor or memory pillar with small footprint using O-ion implantation and post high temperature rapid thermal annealing. The first step is to deposit a full stack of MTJ multi-layer on a substrate in one pump down vacuum which, for example, contains a bottom seed (200), a a magnetic reference layer (210), a MgO tunnel barrier layer (220), a magnetic sensing or memory recording layer (240) and top capping layer (250) shown in FIG. 1(A). It can also contain a bottom seed (200), a magnetic reference layer (210), an MgO tunnel barrier layer(220), a magnetic sensing or memory recording layer(230), an MgO (but with less oxygen content) intermediate barrier layer (240) and top capping layer (250) shown in FIG. 1(B). It can also be a reversed structure, which contain a bottom seed (200), an MgO (but with less oxygen content) intermediate barrier layer (210), a magnetic sensing or memory recording layer(220), an MgO tunnel barrier layer(230), a magnetic reference layer (240) and top capping layer (250) shown in FIG. 1(C). It can also be other variation of these multi-layer layers.

### First Embodiment

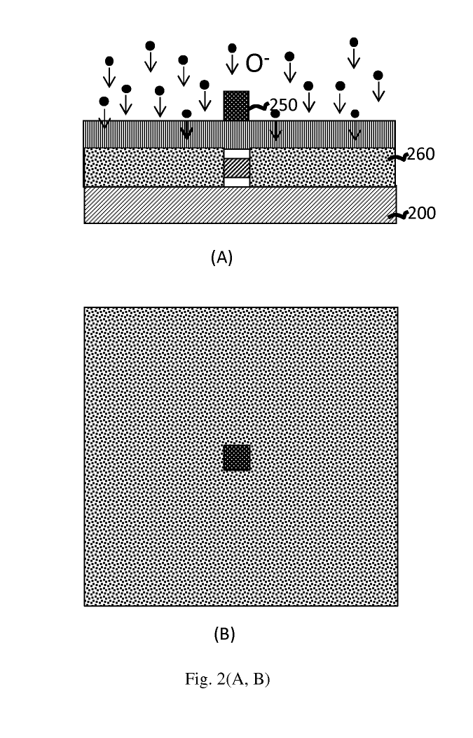

As shown in FIG. 2(A), after the deposition of above films, a photolithography patterning is used to form a small ion implantation mask (250) which can be either the photoresist itself or another material or combination of materials. Then, the exposed area is undergone oxygen ions implantation to drive oxygen ions deep into the MTJ layers to form an oxide region (260).

Then a high temperature (200C-500C) rapid (<5 minutes) thermal anneal is used to help to activate the metal oxidation or MgO crystallization in the implanted area (260) and to repair material structure damage due to ion implantation.

### Second Embodiment

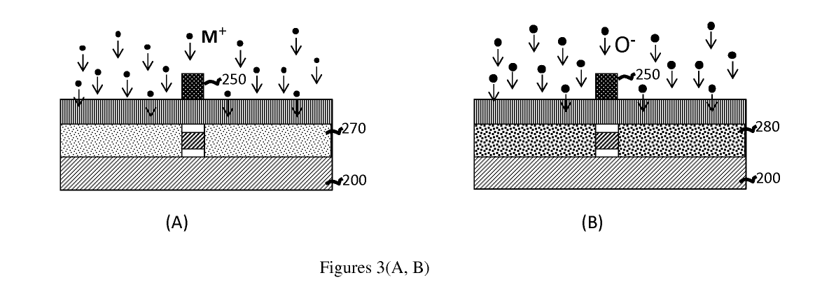

As a second embodiment, some oxygen getter materials, such as Mg, Ca, Zr, Y, Th, Ti, Al, Ba is first implanted into the MTJ region (270), as shown in FIG. 3(A), and followed by oxygen ion implantation, as shown in FIG. 3(B). One preferred oxygen getter material is Mg due to its very small electro-negativity and a easily formed rocksalt crystalline structure with the newly implanted oxygen atoms in the MTJ layers. Due to an easier oxidation and strong M-0 bonding of these oxygen getter atoms, the implanted region (280) will be oxidized more completely and provide a much high resistance.

### Third Embodiment

As a third embodiment, a top portion of exposed MTJ stack is first etched by RIE or IBE etching process, then subsequently ion-implantation process is conducted.

In the MRAM manufactured by the patterning methods according to these embodiments, both tunnel barrier layer and intermediate barrier layer have been heavily added Mg and fully oxidized in exposed regions, leaving a desired shape for an MTJ element as a functional sensing or memory recording. Since the area resistivity in exposed region is readily altered to be 1000 to 10000 times as large as the area resistivity in still functional MTJ elements underneath masks, an applied electric current would essentially flow across the functional MTJ element. An optional conventional lithographic process can be conducted to pattern a much larger region covering above ion-implantation patterned MTJ element. Spin transfer switching characteristics of magnetoresistive elements used in memory cells can be improved due to less damage and side shunting. Further, the magnetoresistive elements are manufactured with a much improved uniformity in cell resistance, which benefits both reading and writing processes. Accordingly, MRAMs manufactured according to these embodiments would have high productivity.

While certain embodiments have been described above, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A method of manufacturing a magnetic tunnel junction device comprising: an MTJ stack is formed on a substrate, the MTJ consists of a recording layer, a reference layer and a tunnel barrier layer disposed between the recording layer and the reference layer, a protective cap layer and an optional intermediate barrier layer provided on a surface of the recording layer, which is opposite to a surface of the recording layer where the tunnel barrier layer is provided, and there is provided a method of patterning a magnetic tunnel junction which comprises:
forming a mask having an opening exposed area on the cap layer;
optionally ion-implanting oxygen getter material to the depth position of the tunnel barrier layer from a surface of the cap layer exposed in the opening of the mask;
ion-implanting oxygen atoms to the depth positions of the tunnel barrier layer and the optional intermediate barrier layer from a surface of the cap layer exposed in the opening of the mask;
carrying out a thermal annealing with respect to the substrate to oxidize an ion implantation region and re-crystallize both the tunnel barrier layer and the optional intermediate barrier layer so that highly oxidized layers having a greatly increased resistance are formed and an oxidized recording layer having a highly increased resistance and zero or near zero magnetization moment is formed in the opening of the mask; and forming a dielectric region outside of the photo-mask on the substrate and a functional magnetoresistive element underneath the photo-mask on the substrate;
removing the mask.

2. The element of claim 1, wherein said tunnel barrier layer is preferred to be a metal oxide or nitride layer selected from MgO, MgZnO, CdO, MgCdO, MgN, MgON.

3. The element of claim 1, wherein said tunnel barrier layer is preferred to be a non-fully oxidized or a non-fully nitrided metal layer selected from MgO, MgZnO, CdO, MgCdO, MgN, MgON.

4. The element of claim 1, wherein said optional intermediate barrier layer is preferred to be a non-fully oxidized metal layer MₓO₁₋ₓ (x>50%), the metal material M is selected from Mg, Zn, Cd, Ca.

5. The element of claim 1, wherein said optional intermediate barrier layer is preferred to be a non-fully nitrided metal layer MₓN₁₋ₓ (x>50%), the metal material M is selected from Mg, Zn, Cd, Ca.

6. The element of claim 1, wherein said magnetic reference layer is a single layer having a fixed magnetization direction, or a synthetic anti-ferromagnetic layer stack having fixed anti-parallel magnetizations in its two anti-parallel coupling layers and having optional anti-ferromagnetic pinning layer.

7. The element of claim 1, wherein said the MTJ sensor/memory element region is protected by said mask which could be the photoresist itself of another material or combination of the materials.

8. The element of claim 1, wherein said oxygen ions are implanted into said exposed area with varied depth covering the entire MTJ film stack.

9. The element of claim 1, wherein said magnetic tunneling junction region is first implanted with said oxygen getter atoms with easy oxidation followed by oxygen ions implantation.

10. The element of claim 1, wherein said oxygen getter atoms are Mg, Zr, Hf, Y, Th, Ti, Al, Ba, Ca, which interact with oxygen ions to form stronger metal-oxygen bonding.

11. The element of claim 1, wherein said oxygen getter material is preferred to be Mg.

12. The element of claim 1, wherein said the oxygen ions implanted MTJ wafer is thermally annealed at a temperature ranging from 200 degree C.-400 degree C.

13. The element of claim 1, wherein said the oxygen ions implanted MTJ wafer is rapidly (between 30 second to 5 minutes) annealed at a temperature ranging from 200 degree C.-600 degree C.

14. The element of claim 1, further comprising an optional etching or milling process to remove a top portion of the MTJ stack after said mask is formed.

15. The element of claim 1, further comprising an optional refilling of a dielectric layer after said thermal annealing, and further comprising an optional CMP process to flatten the top surface after said mask removing.

16. The element of claim 1, wherein said mask is preferred to have vertical edges or edges having angles of at least 75-degree.

17. The element of claim 1, wherein the area resistivity in said exposed area is preferred to be increased by a factor of at least 100 times after said ion-implantation process.

18. The element of claim 1, further comprising a conventional lithographic patterning process to make a larger area centered by said ion-implantation patterned MTJ element to electrically separate from adjacent MTJ elements, followed by dielectric refilling process, lifting-off of mask and CMP process.
